(19) United States
(12) Patent Application Publication
(10) Pub. No.: US 2013/0146729 A1
(43) Pub. Date: Jun. 13, 2013

(54) BRACKET MODULE FOR HARD DISK DRIVE

(71) Applicant: LI-REN FU, Shenzhen City (CN)

(72) Inventor: LI-REN FU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/433,309

(22) Filed: Mar. 29, 2012

(30) Foreign Application Priority Data
Dec. 12, 2011 (CN) 201110411572.5

(51) Int. Cl. H05K 7/00

(52) U.S. Cl. 248/309.1

(57) ABSTRACT

A bracket module includes a first bracket receiving a first hard disk drive (HDD) and a second bracket receiving a second HDD. The first bracket includes a first bottom plate and two first side plates perpendicularly extending from the first bottom plate. The first bottom plate forms a first engaging portion. Each second bracket includes a second bottom plate, two second side plates perpendicularly extending from the second bottom plate, a plate bestriding the second side plates, and a mounting tab with a fastening portion located above the plate. The second bottom plate forms a second engaging portion. A tab extends from the plate to engage in the first engaging portion. A fastener is operable to extend through the fastening portion and the corresponding first side plate to engage in a locking hole defined in the first HDD.

### BACKGROUND

1. Technical Field

The present disclosure relates to a bracket module for hard disk drives (HDDs).

2. Description of Related Art

The number of HDDs mounted in a computer sometimes varies depending on what is required. Designing of receiving space of the HDDs with brackets is based on a situation using the highest number of the HDDs, which lacks flexibility and wastes space.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of a bracket module together with hard disk drives (HDDs), and a rack.

FIG. 2 is an enlarged view of one of the HDDs of FIG. 1.

FIG. 3 is an exploded, isometric view of an exemplary embodiment of the bracket module of FIG. 1.

FIG. 4 is an inverted view of FIG. 3.

FIG. 5 is an assembled, isometric view of FIG. 3.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

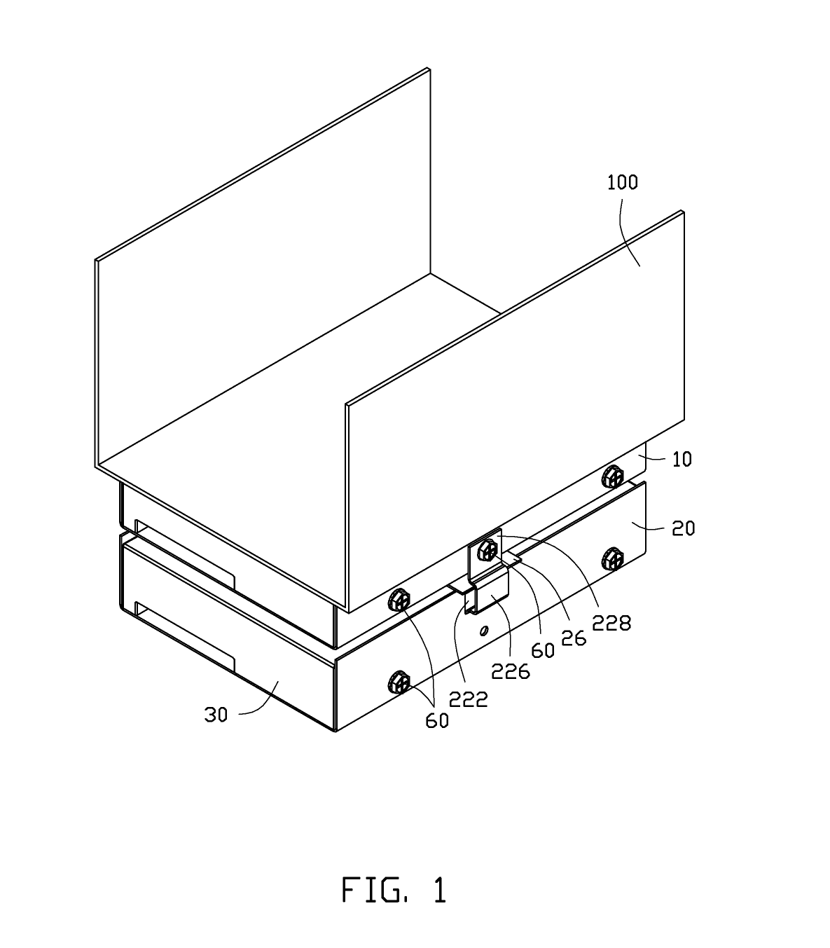

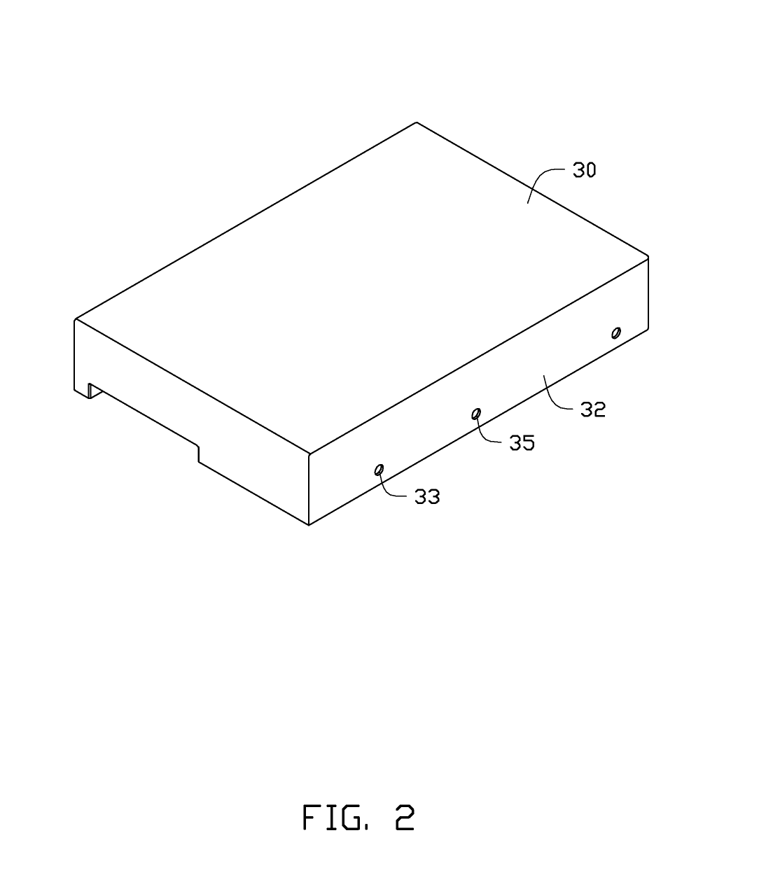

FIGS. 1 and 2 show an exemplary embodiment of a bracket module for mounting two hard disk drives (HDDs) 30. The bracket module includes a first bracket 10 mounted to a rack 100 and a second bracket 20.

The HDD 30 includes two opposite sidewalls 32. Two spaced mounting holes 33 are defined in each sidewall 32. A locking hole 35 is defined in one of the sidewalls 32, between the mounting holes 33.

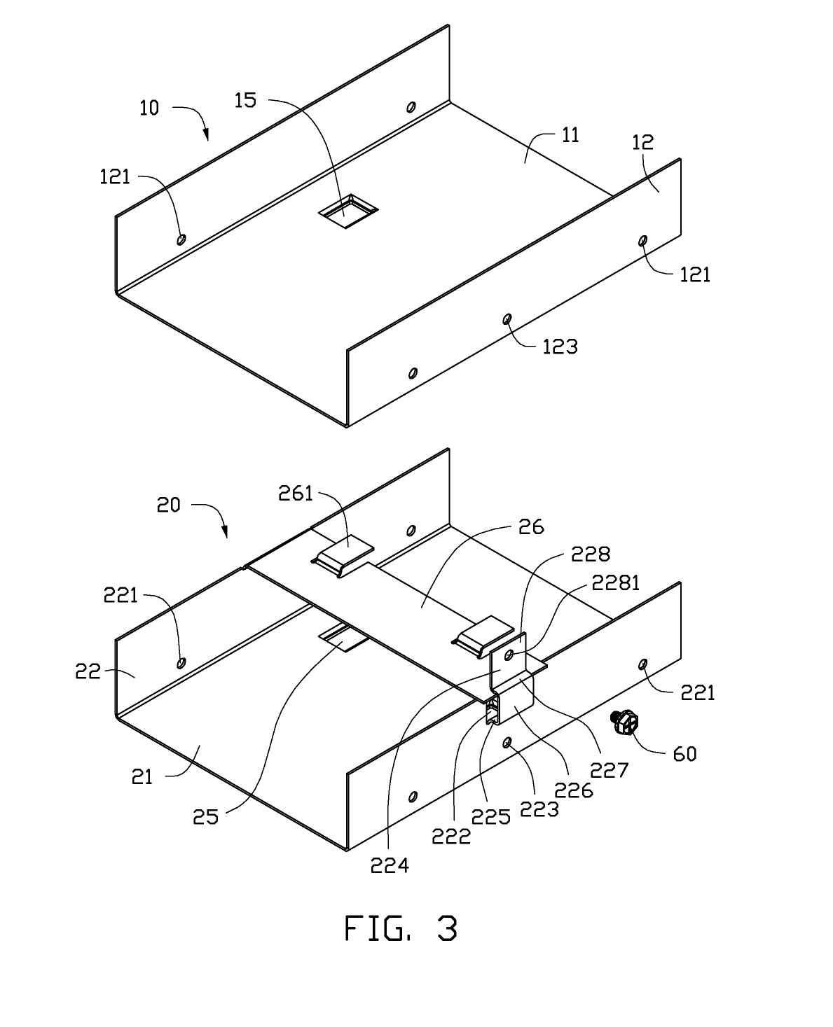

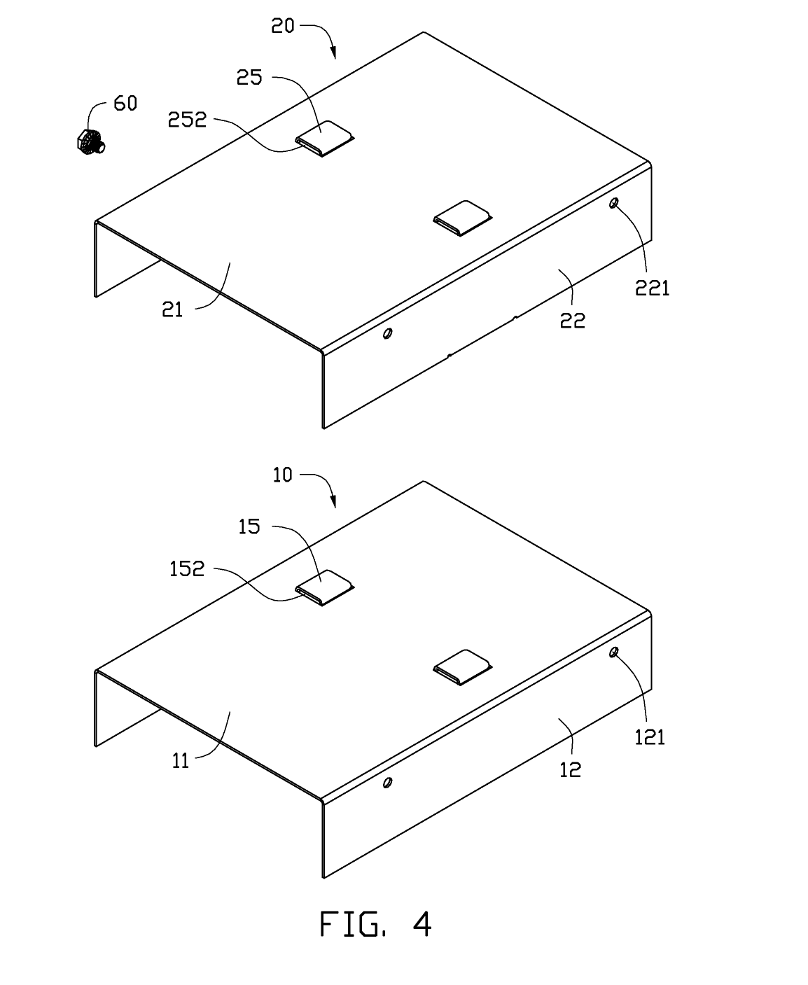

FIGS. 3 and 4 show the first bracket 10 including a first bottom plate 11 and two first side plates 12 perpendicularly extending up from opposite sides of the first bottom plate 11. Two spaced through holes 121 are defined in each first side plate 12. A first positioning hole 123 is defined in one of the first side plates 12, between the through holes 121. The first bottom plate 11 forms two engaging portions 15. Each engaging portion 15 is depressed down from the first bottom plate 11. An opening 152 is defined in a front end of each engaging portion 15.

The second bracket 20 includes a second bottom plate 21 and two second side plates 22 perpendicularly extending up from opposite sides of the second bottom plate 21. Two spaced through holes 221 are defined in each second side plate 22. A second positioning hole 223 is defined in one of the second side plates 22, between the through holes 221. The second bottom plate 21 forms two engaging portions 25. Each engaging portion 25 is depressed down from the second bottom plate 21. An opening 252 is defined in a front end of each engaging portion 25.

A plate 26 is perpendicularly connected between middle of top sides of the second side plates 22, bestriding the second side plates 22. An end of the plate 26 adjacent to the second positioning hole 223 extends out of the corresponding second side plate 22. A notch 222 is defined in the second side plate 22 defining the second positioning hole 223, below the plate 26. A mounting tab 224 extends from a bottom wall bounding the notch 222. The mounting tab 224 includes an extension portion 225 extending out from the bottom wall bounding the notch 222 of the second side plate 22, a connection portion 226 extending up from a side of the extension portion 225 away from the second side plate 22, an abutting portion 227 extending toward the second side plate 22 from a top side of the connection portion 226 and abutting against a top surface of the plate 26, and a fastening portion 228 perpendicularly extending up from a side of the abutting portion 227 away from the connection portion 226. A through hole 2281 is defined in the fastening portion 228. An inner side surface of the fastening portion 228 is coplanar with an outer side surface of the second side plate 22 defining the second positioning hole 223. Two substantially L-shaped tabs 261 extend from the plate 26. Each tab 261 extends up and then extends backward.

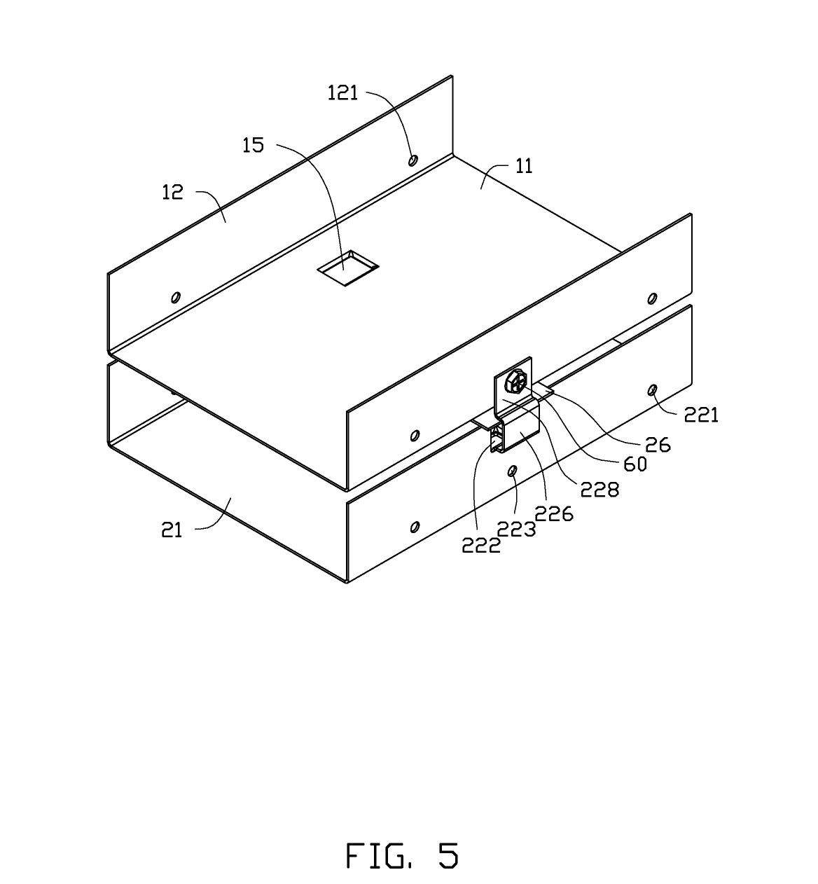

FIGS. 1 and 5 show assembly, the two HDDs 30 are respectively received in the first bracket 10 and the second bracket 20. The locking holes 35 respectively align with the first positioning hole 123 and the second positioning hole 223. A plurality of screws 60 extends through the through holes 121 and 221, and then engages in the corresponding mounting holes 33. Therefore, the HDDs 30 are respectively fastened to the first bracket 10 and the second bracket 20.

The second bracket 20 is placed below the first bracket 10. The tabs 261 engage in the corresponding engaging portions 15 through the corresponding openings 152. The fastening portion 228 abuts against the corresponding first side plate 12. The through hole 2281 aligns with the first positioning hole 123 and the locking hole 35 of the HDD 30 received in the first bracket 10. A fastener 60, such as a screw, extends through the through hole 2281 and the first positioning hole 123, and then engages in the corresponding locking hole 35. Therefore, the second bracket 20 is mounted to the first bracket 10.

When more HDDs 30 are required, more HDDs 30 can be respectively received in other second brackets 20. The other second brackets 20 are mounted in turn below the second bracket 20 as described above.

In a second embodiment, the mounting tab 224 is omitted, and the fastening portion 228 directly extends up from the plate 26, in response to the plate 26 being fixed on the second side plate 22 defining the second positioning hole 223.

It is believed that the present embodiments and their advantages will be understood from the foregoing description, and various changes may be made thereto without departing from the spirit and scope of the description or sacrificing all of their materials advantages, the examples hereinbefore described merely being exemplary embodiments.

What is claimed is:

1. A bracket module for two hard disk drives (HDDs), comprising:
a first bracket comprising a first bottom plate and two first side plates perpendicularly extending up from the first bottom plate to receive one of the HDDs, the first bottom plate forming a first engaging portion; and
a second bracket comprising a second bottom plate, two second side plates perpendicularly extending up from the second bottom plate to receive the other one of the HDDs, a plate bestriding the second side plates, and a mounting tab adjacent to one of the second side plates and comprising a fastening portion located above the plate, a tab extending from the plate to engage in the first engaging portion, a fastener operable to extend through the fastening portion and a corresponding one of the first side plates to engage in a sidewall of the corresponding HDD.

2. The bracket module of claim 1, wherein the first engaging portion is depressed down from the first bottom plate, an opening is defined in an end of the engaging portion for the tab of the plate extending through.

3. The bracket module of claim 1, wherein the plate is connected between tops of the second side plates.

4. The bracket module of claim 3, wherein the mounting tab extends from the corresponding second side plate of the second bracket, the mounting tab further comprises an extension portion extending out from the second side plate, a connection portion extending up from a side of the extension portion opposite to the second side plate, an abutting portion extending toward the plate from a top side of the connection portion and abutting against a top surface of the plate, the fastening portion extends up from the abutting portion.

5. The bracket module of claim 1, wherein a second engaging portion is depressed down from the second bottom plate.

6. A bracket for a hard disk drive (HDD), comprising:
a bottom plate comprising an engaging portion;
two side plates perpendicularly extending from opposite sides of the bottom plate, the bottom plate and the side plates cooperatively hold the HDD;
a plate bestriding the side plates, a tab extending rearward from the plate; and
a mounting tab located adjacent to one of the side plates and comprising a fastening portion located above the plate.

7. The bracket of claim 6, wherein the engaging portion is depressed down from the bottom plate, an opening is defined in an end of the engaging portion.

8. The bracket of claim 6, wherein the plate is connected between tops of the side plates.

9. The bracket of claim 8, wherein the mounting tab extends from the corresponding one of the side plates, the mounting tab further comprises an extension portion extending out from the second side plate, a connection portion extending up from a side of the extension portion opposite to the side plate, an abutting portion extending toward the plate from a top of the connection portion to abut against the plate, the fastening portion extends up from the abutting portion.
